(19) United States
(12) Patent Application Publication
(10) Pub. No.: US 2022/0393020 A1
(43) Pub. Date: Dec. 8, 2022

(54) METHOD FOR FABRICATING SEMICONDUCTOR STRUCTURE AND STRUCTURE THEREOF

(71) Applicant: CHANGXIN MEMORY TECHNOLOGIES, INC., Hefei (CN)

(72) Inventors: Youming LIU, Hefei (CN); Deyuan XIAO, Hefei (CN)

(21) Appl. No.: 17/891,113

(22) Filed: Aug. 18, 2022

(30) Foreign Application Priority Data
Jun. 15, 2022 (CN) 202210682040.3

(51) Int. Cl. H01L 29/66; H01L 27/108

(52) U.S. Cl. CPC H01L 29/66666; H01L 29/66787; H01L 29/6656; H01L 29/6653; H01L 27/10885; H01L 27/10891

(57) ABSTRACT

Embodiments provide a method for fabricating a semiconductor structure. The method includes: providing a substrate, where the substrate includes semiconductor channels arranged in an array along a first direction and a second direction, and a part of the substrate is exposed between adjacent semiconductor channels; forming a spacer positioned between adjacent semiconductor channels, where a top surface of the spacer is lower than top surfaces of the semiconductor channels; forming a bit line positioned in the substrate, where a top surface of the bit line contacts and connects bottom surfaces of the semiconductor channels; forming a protective layer, where a part of the protective layer is positioned on the top surface of the spacer between the semiconductor channels arranged along the second direction, and another part of the protective layer is positioned on the top surface of the spacer between the semiconductor channels arranged along the first direction.

### CROSS-REFERENCE TO RELATED APPLICATION

This application claims priority to Chinese Patent Application No. 202210682040.3, titled “METHOD FOR FABRICATING SEMICONDUCTOR STRUCTURE AND STRUCTURE THEREOF” and filed to the State Patent Intellectual Property Office on Jun. 15, 2022, the entire contents of which are incorporated herein by reference.

### TECHNICAL FIELD

The present disclosure relates to the field of semiconductors, and more particularly, to a method for fabricating a semiconductor structure and a structure thereof.

### BACKGROUND

As an integration density of dynamic memories develops towards a higher direction, when it is made a study of arrangement of transistors in a dynamic memory array structure and how to reduce a size of a single functional device in the dynamic memory array structure, it is also required to improve electrical properties of small-sized functional devices.

When a vertical gate-all-around (GAA) transistor structure is used as a dynamic memory access transistor, an area occupied by the vertical GAA transistor structure may reach 4F² (F: a smallest pattern size attainable under a given process condition), and in principle, higher density efficiency may be achieved.

It is disclosed, however, that at present, a source or drain may be damaged or contaminated during fabrication.

### SUMMARY

Embodiments of the present disclosure provide a method for fabricating a semiconductor structure and a structure thereof, to at least facilitate solving a problem that a source or drain may be damaged or contaminated during fabrication.

According to some embodiments of the present disclosure, one aspect of the embodiments of the present disclosure provides a method for fabricating a semiconductor structure. The method includes: providing a substrate, where the substrate includes semiconductor channels arranged in an array along a first direction and a second direction, and a part of the substrate is exposed between adjacent semiconductor channels; forming a spacer positioned between the adjacent semiconductor channels, where a top surface of the spacer is lower than top surfaces of the semiconductor channels; forming a bit line positioned in the substrate, where a top surface of the bit line contacts and connects bottom surfaces of the semiconductor channels; forming a protective layer, where a part of the protective layer is positioned on the top surface of the spacer between the semiconductor channels arranged along the second direction, and another part of the protective layer is positioned on the top surface of the spacer between the semiconductor channels arranged along the first direction; and forming a word line positioned between the protective layer and the spacer.

In some embodiments, the step of the forming the spacer includes: forming first spacers, where part of the first spacers are arranged at intervals along the first direction, and the first spacers are positioned between the semiconductor channels arranged along the second direction; forming side wall layers, where the side wall layers cover side walls of the semiconductor channels arranged at intervals along the first direction, and the side wall layers also cover side walls of the first spacers arranged at intervals along the first direction; and forming second spacers, where the second spacers are positioned between adjacent side wall layers, and the first spacers, the side wall layers and the second spacers constitute the spacer.

In some embodiments, the step of forming the protective layer includes: forming a first protective layer, where the first protective layer is positioned on top surfaces of the first spacers; and forming second protective layers, where the second protective layers is positioned on side walls of the first protective layers arranged at intervals along the first direction. The second protective layers further cover the side walls of the semiconductor channels arranged at intervals along the first direction, and the first protective layers and the second protective layers constitute the protective layer.

In some embodiments, the forming the first protective layers includes: forming first initial protective layers before the side wall layers are formed, where the first initial protective layers are positioned on top surfaces of the first spacers and extend along the first direction; and etching the first initial protective layers to form the first protective layers arranged at intervals along the first direction.

In some embodiments, the forming the second protective layers includes: forming second initial protective layers after the second spacers are formed, where the second initial protective layers cover the side walls of the first protective layers, top surfaces of the side wall layers, and entire top surfaces of the second spacers; and etching the second initial protective layers to form the second protective layers arranged at intervals along the first direction.

In some embodiments, the step of forming the protective layer includes: forming an initial protective layer after the second spacers are formed, where the initial protective layer cover the entire top surface of the spacer, and the initial protective layer further cover part of the side walls of the semiconductor channels arranged at intervals along the first direction; and etching the initial protective layer to form the protective layer arranged at intervals along the first direction.

In some embodiments, a material of the protective layer is different from a material of the spacer.

In some embodiments, a thickness of the protective layer formed is controlled within 20-70 nm in a direction perpendicular to a surface of the substrate.

In some embodiments, the step of forming the bit line includes: forming a bit line metal layer, where the bit line metal layer is positioned between adjacent semiconductor channels arranged at intervals along the first direction; converting a part of the substrate into an initial bit line by means of a first annealing process; removing the bit line metal layer; and converting the initial bit line into the bit line by means of a second annealing process.

In some embodiments, a process temperature of the first annealing process is lower than a process temperature of the second annealing process.

In some embodiments, the process temperature of the first annealing process is 400° C. to 700° C., and the process temperature of the second annealing process is 750° C. to 1,000° C.

In some embodiments, the forming the word line includes: etching the spacer to expose the side walls of the semiconductor channels; forming an initial word line, where the initial word line is positioned on the top surface of the spacer; and etching the initial word line using the protective layer as a mask until the spacer is exposed, where a remaining part of the initial word line is used as the word line.

In some embodiments, before forming the initial word line, the method further includes: forming a gate dielectric layer, where the gate dielectric layer covers the side walls of the semiconductor channels.

In some embodiments, after forming the gate dielectric layer, the method further includes: forming a diffusion barrier layer, where the diffusion barrier layer is positioned on the top surface of the spacer.

According to some embodiments of the present disclosure, another aspect of the embodiments of the present disclosure further provides a semiconductor structure, which is formed by using the above-mentioned method for fabricating a semiconductor structure.

The technical solutions provided by the embodiments of the present disclosure have at least the following advantages: a protective layer is formed on a side wall of a semiconductor channel and a top surface of a spacer, and a part of the semiconductor channel configured to form a source or drain is protected by the protective layer, such that the source or drain may be prevented from being oxidized or damaged in subsequent process steps. In this way, reliability of the source or drain of the semiconductor structure may be improved, and thus reliability of the semiconductor structure is improved.

### BRIEF DESCRIPTION OF THE DRAWINGS

Exemplary descriptions are made to one or more embodiments with reference to pictures in the corresponding drawings, and these exemplary descriptions do not constitute limitations on the embodiments. Unless otherwise stated, the figures in the accompanying drawings do not constitute a scale limitation. To describe the technical solutions of the embodiments of the present disclosure or those of the prior art more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIGS. 1 to 14 are schematic structural diagrams corresponding to steps of a method for fabricating a semiconductor structure according to an embodiment of the present disclosure;

FIGS. 15 to 23 are schematic structural diagrams corresponding to steps of a method for fabricating a semiconductor structure according to another embodiment of the present disclosure.

### DETAILED DESCRIPTION

As can be known from the background art, at present, a protective layer needs to be etched in the process of forming a word line, then a semiconductor channel exposed by etching the protective layer is oxidized to form a gate dielectric layer, then metal is deposited to form a word line, and then a part of a top of the semiconductor channel configured to form a source or drain in the process of oxidizing the semiconductor channel is exposed to air, which possibly causes this part of the semiconductor channel configured to form the source or drain to be oxidized in the process of forming a gate dielectric layer, or, when a metal material of the word line is deposited subsequently, the metal material is also attached to a surface of the source or drain, thereby causing reliability of the semiconductor structure to be reduced.

The embodiments of the present disclosure provide a method for fabricating a semiconductor structure. The protective layer is formed on a top surface of a spacer between adjacent semiconductor channels arranged along a second direction and on the top surface of the spacer between the adjacent semiconductor channels arranged along a first direction. That is, the source or drain surrounding the semiconductor channels forms the protective layer, which can protect a region of each semiconductor channel configured to form the source or drain, such that the source or drain may be prevented from being oxidized when the gate dielectric layer is formed subsequently, and the metal material may be prevented from being attached to the region of each semiconductor channel configured to form the source or drain in the process of subsequently deposing the metal material of the word line, and thus the reliability of the semiconductor structure may be improved.

The embodiments of the present disclosure will be described in detail below in conjunction with the accompanying drawings. However, a person of ordinary skill in the art may understand that in the embodiments of the present disclosure, many technical details are put forward such that a reader may better understand the present disclosure. However, the technical solutions requested to be protected by the present disclosure may also be implemented even without these technical details or various variations and modifications based on the following embodiments.

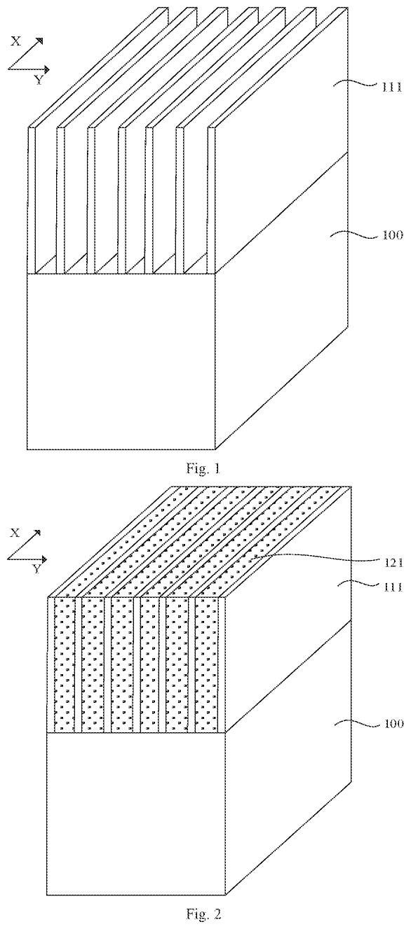

Referring to FIGS. 1 to 9, a substrate 100 is provided, the substrate 100 includes semiconductor channels 110 arranged in an array along a first direction X and a second direction Y, and part of the substrate 100 is exposed between adjacent semiconductor channels 110. A spacer 120 is formed, the spacer 120 is positioned between adjacent semiconductor channels 110, where a top surface of the spacer 120 is lower than top surfaces of the semiconductor channels 110. A bit line 130 is formed, the bit line 130 is positioned in the substrate 100, where a top surface of the bit line 130 contacts and connects bottom surfaces of the semiconductor channels 110. A protective layer 140 is formed, where a part of the protective layer 140 is positioned on the top surface of the spacer 120 between the semiconductor channels 110 arranged along the second direction Y, and another part of the protective layer 140 is positioned on the top surface of the spacer 120 between the semiconductor channels 110 arranged along the first direction X. By forming, in the semiconductor channels 110, the protective layer 140 surrounding the semiconductor channels 110, and by providing the protective layer 140 surrounding the source or drain of the semiconductor channel 110, the source or drain of the semiconductor channel 110 may be prevented from being adversely affected in subsequent process steps, such that the reliability of the semiconductor structure can be improved.

In some embodiments, referring to FIG. 1, the substrate 100 is provided, and the substrate 100 is patterned to form initial semiconductor channels 111 arranged at intervals along the second direction Y.

In some embodiments, a material of the substrate 100 may be a material such as silicon, germanium, or silicon germanium, and the material of the substrate 100 may also be doped with other materials. Taking an example where the material of the substrate 100 is silicon, the substrate 100 may be doped with a small amount of trivalent element such as boron, indium, gallium or aluminum, such that a P-type substrate may be formed. Similarly, the substrate 100 is doped with a small amount of pentavalent element such as phosphorus, antimony or arsenic, such that an N-type substrate may be formed. Elements doped into the substrate 100 may be selected based on aspects such as actual requirements and product performance, and the present disclosure does not limit the material of the substrate 100 or the elements doped into the substrate 100.

In some embodiments, the initial semiconductor channels 111 may be formed by means of a self-aligned double patterning (SADP) process. In some other embodiments, the initial semiconductor channels 111 may also be formed by means of a self-aligned quadruple patterning (SAQP) process. The initial semiconductor channels 111 formed may have more accurate patterns by means of the SADP or SAQP process.

Referring to FIG. 2, a first initial spacer 121 is formed, where the first initial spacer 121 fills up a gap between adjacent initial semiconductor channels 111. Forming the first initial spacer 121 may provide a process basis for subsequent formation of a first spacer, and may also isolate adjacent initial semiconductor channels 111.

In some embodiments, forming the first initial spacer 121 may include: filling a material of the first initial spacer 121 between adjacent initial semiconductor channels 111 until a top surface of the first initial spacer 121 is flush with top surfaces of the initial semiconductor channels 111. In some other embodiments, when filling the material of the first initial spacer 121, the first initial spacer 121 formed also covers the top surfaces of a part of the initial semiconductor channel sill, and a part of the first initial spacer 121 is removed by means of etching back until the top surface of the first initial spacer 121 is flush with the top surfaces of the initial semiconductor channels 111.

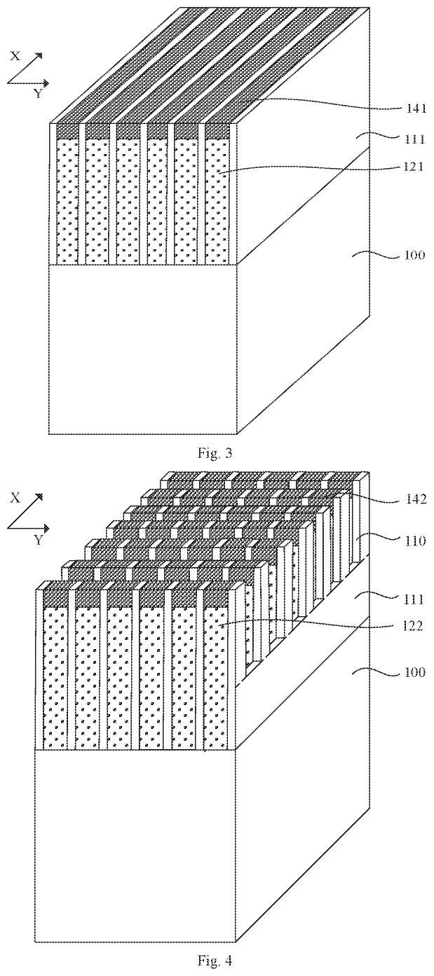

Referring to FIG. 3, the first initial spacer 121 is etched back, such that the top surface of the first initial spacer 121 is lower than the top surfaces of the initial semiconductor channels 111. A first initial protective layer 141 is formed, where the first initial protective layer 141 is positioned on the top surface of the first initial spacer 121 and extends along the first direction X. In some other embodiments, the first initial protective layer 141 also covers the top surfaces of the initial semiconductor channels 111 in the process of forming the first initial protective layer 141, and a part of the first initial protective layer 141 is removed by means of chemical mechanical polishing until the top surface of the first initial protective layer 141 is flush with the top surfaces of the initial semiconductor channels 111.

Referring to FIG. 4, first spacers 122 are formed, part of the first spacers 122 are arranged at intervals along the first direction X, and the first spacers 122 are positioned between the semiconductor channels 110 arranged along the second direction X. The semiconductor channels 110 are formed, and the semiconductor channels 110 are arranged at intervals along the first direction X and the second direction Y. First protective layers 142 are formed, and the first protective layers 142 are positioned on top surfaces of the first spacers 122.

In some embodiments, the first spacers 122, the semiconductor channels 110 and the first protective layers 142 are formed in the same step. The first initial spacer 121, the initial semiconductor channels 111, and the first initial protective layer 141 may be etched by means of SADP to form the first spacers 122, the semiconductor channels 110 and the first protective layers 142 arranged at intervals along the first direction X. In some other embodiments, the first initial spacer 121, the initial semiconductor channels 111 and the first initial protective layer 141 may also be etched by means of mask etching.

In some embodiments, only part of the initial semiconductor channels are etched in the process of forming the semiconductor channels 110, such that part of the initial semiconductor channels 111 are arranged at intervals in the first direction X, and this part of the initial semiconductor channels 111 arranged at intervals are used as the semiconductor channels 110.

It is to be understood that projections of the first spacers 122 on the surface of the substrate 100 are consecutive along the first direction X, and the first spacers 122 positioned between the semiconductor channels 110 arranged at intervals along the second direction Y are arranged at intervals along the first direction X. That is, the first spacers 122 arranged in parallel to the semiconductor channels 110 along the second direction Y are arranged at intervals along the first direction X, and the first spacers 122 arranged in parallel to the initial semiconductor channels 111 along the second direction Y are consecutive in the first direction X.

Forming the first protective layers 142 may cover two side walls of each of the semiconductor channels 110 oppositely arranged along the second direction Y, such that the two side walls of each of the semiconductor channels 110 oppositely arranged along the second direction Y may be protected by forming the first protective layers 142.

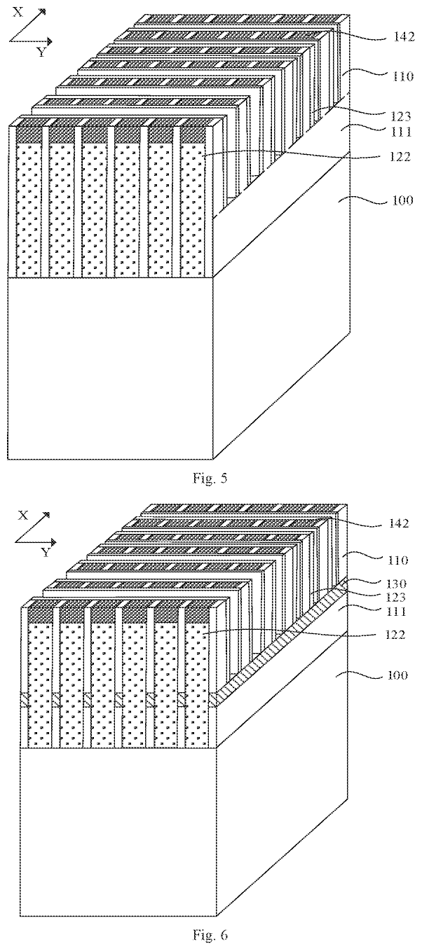

Referring to FIGS. 5 to 8, the step of forming the spacer 120 further includes: forming side wall layers 125, where the side wall layers 125 cover side walls of the semiconductor channels 110 arranged at intervals along the first direction X, and the side wall layers 125 also cover side walls of the first spacers 122 arranged at intervals along the first direction X; and forming second spacers 126, where each of the second spacers 126 is positioned between adjacent side wall layers 125, and the first spacers 122, the side wall layers 125, and the second spacers 126 constitute the spacer 120. By forming the spacers 120, a word line formed subsequently may be isolated from the bit line 130, such that electric connection between the word line and the bit line 130 may be avoided.

Referring to FIG. 5, initial side wall layers 123 are formed, where the initial side wall layers 123 cover the side walls of the semiconductor channels 110 arranged at intervals along the first direction X, the initial side wall layers 123 also cover the side walls of the first spacers 122 arranged at intervals along the first direction X, and the initial side wall layers 123 also cover the side walls of the first protective layers 142 arranged at intervals along the first direction X.

In some embodiments, forming the initial side wall layers 123 may include following steps. An insulating material is deposited, by means of atomic layer deposition, in trenches formed by etching the first initial spacer 121 (referring to FIG. 3), the initial semiconductor channels 111, and the first initial protective layer 141 (referring to FIG. 3). The initial side wall layers 123 covering side walls and bottom surfaces of the trenches may be formed by means of atomic layer deposition, and then part of the initial side wall layers 123 covering the bottom surfaces of the trenches are removed by means of etching to form the initial side wall layers 123 arranged at intervals along the first direction X. Forming the initial side wall layers 123 may prevent metal ions from diffusing into the semiconductor channels 110 when subsequently forming the bit line, such that the semiconductor channels 110 are prevented from being polluted, and thus the reliability of the semiconductor structure formed may be improved.

Referring to FIG. 6, the bit line 130 is formed. In some embodiments, the step of forming the bit line 130 may include: forming a bit line metal layer (not shown in the figure), where the bit line metal layer is positioned between the semiconductor channels 110 arranged at intervals along the first direction X; converting a part of the substrate 100 into an initial bit line by means of a first annealing process; removing the bit line metal layer; and converting the initial bit line into the bit line 130 by means of a second annealing process. A contact resistance between the bit line 130 formed by means of the metal-semiconductor compound process and the substrate 100 is lower, such that the performance of the semiconductor structure formed can be improved.

In some embodiments, a bit line metal layer may be formed between the initial side wall layers 123. By taking an example where the bit line metal layer is made of titanium metal, a titanium nitride film may also be deposited on a surface of the titanium metal after the titanium metal is deposited, where the titanium nitride film may prevent the titanium metal from flowing during rapid thermal annealing. First rapid thermal annealing is performed, such that the titanium metal reacts with monocrystalline silicon of the initial semiconductor channels 111 to generate a high-impedance initial bit line. The titanium metal and the titanium nitride film may be removed by means of selective wet etching. Second rapid thermal annealing is performed, such that the high-impedance initial bit line may be converted into a low-impedance bit line 130. It is to be understood that the titanium nitride film, the titanium metal and the monocrystalline silicon are only examples taken for the convenience of description, and do not limit the material of the metal layer, the film on the metal layer and the material of the initial semiconductor channels 111, which may be adjusted according to actual situations.

In some embodiments, the process temperature of the first annealing process may be lower than the process temperature of the second annealing process. By setting a lower temperature of the first annealing process, the bit line metal layer may react only with the material of the substrate 100 to generate a high-impedance metal semiconductor compound. By setting a higher temperature of the second annealing process, the high-impedance metal silicide may be converted into a low-impedance metal semiconductor compound, which is used as the bit line 130.

In some embodiments, the process temperature of the first annealing process is 400° C. to 700° C., and the process temperature of the second anneal process is 750° C. to 1,000° C. It is to be understood that, when the process temperature of the first annealing process is lower than 400° C., the effect of converting the substrate 100 into the initial bit line is poor. When the process temperature of the first annealing process is higher than 700° C., the material of the substrate 100 may diffuse along a grain boundary of the initial bit line, causing excessive growth of the metal semiconductor compound of the initial bit line, which may possibly cause part of the initial bit line growing excessively not to be removed in the process of subsequently removing the bit line metal layer by means of etching, and thus possibly causing short circuit. When the process temperature of the second annealing process is lower than 750° C., the effect of converting the initial bit line into the bit line 130 is poor, that is, the effect of converting the high-impedance metal semiconductor compound into the low-impedance metal semiconductor compound is poor, and a resistance of the bit line 130 is adversely affected. When the process temperature of the second annealing process is higher than 1,000° C., the metal semiconductor compound of the bit line 130 may be reduced to a semiconductor material due to thermal stability.

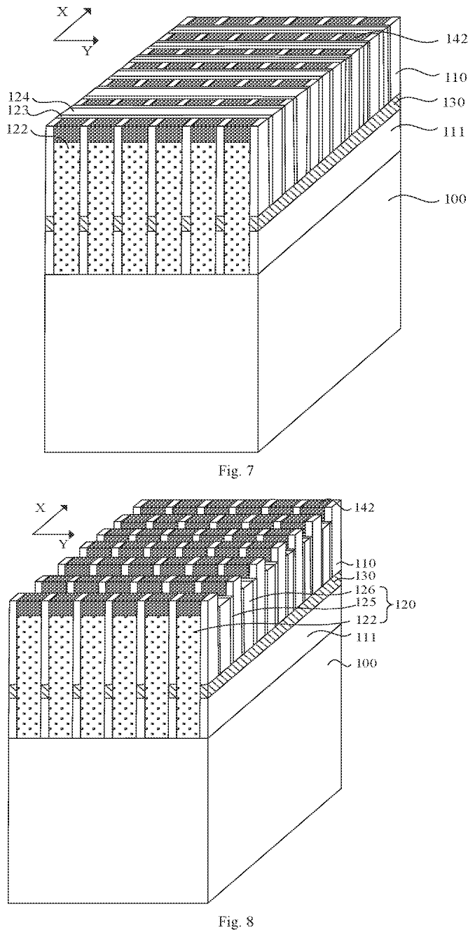

Referring to FIG. 7, a second initial spacer 124 is formed, where the second initial spacer 124 is positioned between adjacent initial side wall layers 123. Forming the second initial spacer 124 may provide a process basis for subsequent isolation of the bit line from the word line.

In some embodiments, the second initial spacer 124 may be formed by depositing an insulating material, and the insulating material is deposited until a top surface of the second initial spacer 124 is flush with the top surfaces of the semiconductor channels 110. In some other embodiments, in the process of forming the second initial spacer 124, the second initial spacer 124 also covers the top surfaces of the semiconductor channels 110, and a part of the second initial spacer 124 may be removed by means of etching back, such that the top surface of the second initial spacer 124 is flush with the top surfaces of the semiconductor channels 110.

In some embodiments, the first spacers 122, the initial side wall layers 123 and the second initial spacer 124 may be made of the same material, which may be an insulating material such as silicon oxide. In some other embodiments, the first spacers, the side wall layers and the second spacers may also be made of different materials.

Referring to FIG. 8, the initial side wall layers 123 (referring to FIG. 7) and the second initial spacer 124 (referring to FIG. 7) are etched back, such that the top surfaces of the initial side wall layers 123 (referring to FIG. 7) and the top surface of the second initial spacer 124 (referring to FIG. 7) are lower than the top surfaces of the first protective layers 142. A remaining part of the initial side wall layers 123 (referring to FIG. 7) and a remaining part of the second initial spacer 124 (referring to FIG. 7) are used as the side wall layers 125 and the second spacers 126. The initial side wall layers 123 and the second initial spacer 124 are etched back to provide a process basis for subsequent formation of the second protective layers.

In some embodiments, top surfaces of the side wall layers 125 and top surfaces of the second spacers 126 are flush with the top surfaces of the first spacers 122. In some other embodiments, the top surfaces of the side wall layers and the top surfaces of the second spacers are higher than or lower than top surfaces of first isolation structures.

It is to be noted that the “flush with” refers to a fact that the top surfaces of the side wall layers 125 and the top surfaces of the second spacers 126 are completely flush with the top surfaces of the first spacers 122, or when a height difference between the top surfaces of the side wall layers 125 and of the second spacers 126 and the top surfaces of the first spacers 122 is within a tolerable error range, it is also regarded that the top surfaces of the side wall layers 125 and the top surfaces of the second spacers 126 are flush with the top surfaces of the first spacers 122.

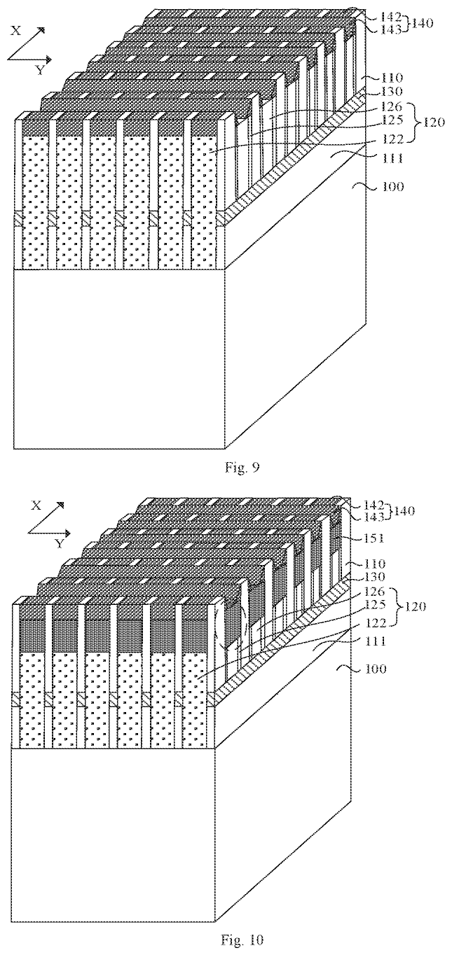

Referring to FIG. 9, a second protective layer 143 is formed, where the second protective layer 143 is positioned on the side walls of the first protective layers 142 spaced along the first direction X, and the second protective layer 143 also covers the side walls of the semiconductor channels 110 spaced along the first direction X. the first protective layer 142 and the second protective layer 143 constitute the protective layer 140. The second protective layers 143 formed may be used as masks of the spaced word lines subsequently formed by means of etching, and the second protective layers 143 may also protect the side walls of the semiconductor channels 110 arranged at intervals along the first direction X. By forming the second protective layers 143, the protective layers 140 surrounding the semiconductor channels 110 may be formed, such that a part of each semiconductor channel 110 configured to form the source or drain may be protected, and the reliability of the semiconductor structure formed may be improved.

In some embodiments, forming the second protective layers 143 may include: forming second initial protective layers (not shown in the figures) after the second spacers 126 are formed, where the second initial protective layers cover the side walls of the first protective layers 142, the top surfaces of the side wall layers 125, and the entire top surfaces of the second spacers 126; and etching the second initial protective layers to form the second protective layers 143 arranged at intervals along the first direction X. A width of each second protective layer 143 formed in the first direction X may be better controlled by first depositing an insulating material to form the second initial protective layers and then forming the second protective layers 143 by means of etching. In some embodiments, the second protective layers 143 and the first protective layers 142 may be made of the same material, such as silicon oxynitride or silicon nitride.

In some embodiments, a projection of the protective layer 140 formed along the second direction Y is trapezoidal. In some other embodiments, the projection of the protective layer 140 formed along the second direction Y may also be rectangular.

In some embodiments, the protective layer 140 and the spacer 120 are made of different materials. The material of the protective layer 140 is controlled to be different from that of the spacer 120, such that the protective layer 140 may be prevented from being etched in the process of subsequently etching the spacer 120, thereby avoiding reducing a protection effect of the protective layer 140.

In some embodiments, a thickness of the protective layer 140 formed is controlled within 20-70 nm in a direction perpendicular to the surface of the substrate 100. It is to be understood that the thickness of the protective layer 140 may be set according to a thickness of the region of each semiconductor channel 110 protected for forming the source or drain. When the thickness of the protective layer 140 is less than 20 nm, a part of the semiconductor channel 110 for forming the source or drain may be not protected, causing poor protection effect. When the thickness of the protective layer 140 is greater than 70 nm, a part of a region of the semiconductor channel 110 for forming a gate may likely be covered. In some other embodiments, the thickness of the protective layer 140 may also be other sizes, and may be adjusted according to actual situations.

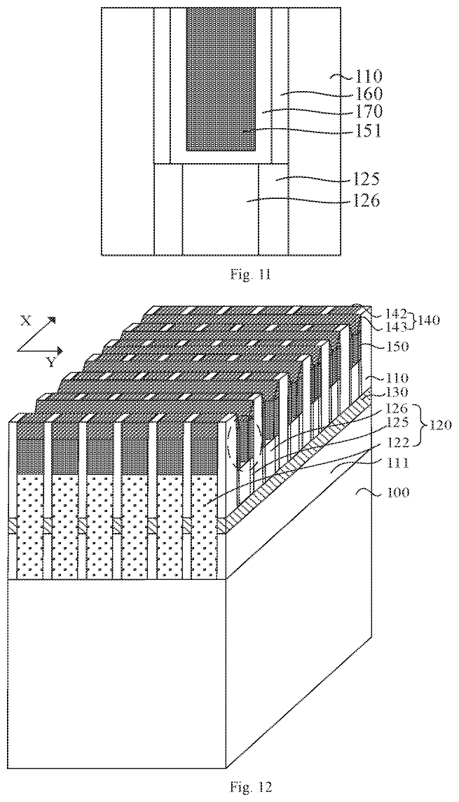

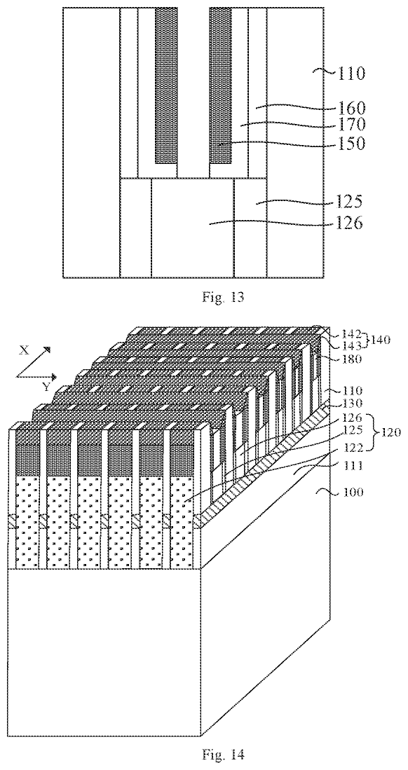

Referring to FIG. 10 to FIG. 13, a word line 150 is formed, where the word line 150 is positioned between the protective layer 140 and the spacer 120. FIG. 11 is a schematic enlarged drawing of a structure within a dotted line in FIG. 10; and FIG. 13 is a schematic enlarged drawing of a structure within a dotted line in FIG. 12.

In some embodiments, referring to FIG. 10 and FIG. 11, in some embodiments, forming a word line may include: etching the spacer 120 to expose the side wall of the semiconductor channel 110; forming an initial word line 151, where the initial word line 151 is positioned on the top surface of the spacer 120.

In some embodiments, before forming the initial word line 151, the method further includes: forming a gate dielectric layer 160, where the gate dielectric layer 160 covers the side wall of the semiconductor channel 110. Forming the gate dielectric layer 160 may prevent direct contact between the word line formed subsequently and the semiconductor channels 110, thereby preventing an exception from occurring in the semiconductor structure.

In some embodiments, the gate dielectric layer 160 may be formed by oxidizing the semiconductor channels 110. In some other embodiments, the gate dielectric layer 160 may also be formed by means of atomic layer deposition. An oxide layer formed on the gate dielectric layer 160 formed by means of oxidation is more compact, and thus the gate dielectric layer 160 has a better effect. The gate dielectric layer 160 formed by means of atomic layer deposition has better uniformity, and a width of the gate dielectric layer 160 formed may be easily controlled.

In some embodiments, after forming the gate dielectric layer 160, the method further includes: forming a diffusion barrier layer 170, where the diffusion barrier layer 170 is positioned on the top surface of the spacer 120. Forming the diffusion barrier layer 170 may prevent metal ions of subsequent word lines from diffusing into the semiconductor channels, thereby avoiding pollution of the semiconductor channels. Furthermore, forming the diffusion barrier layer 170 may improve the reliability of the semiconductor structure.

Referring to FIG. 12 and FIG. 13, the initial word line 151 is etched using the protective layer 140 as a mask until the spacer 120 is exposed, and a remaining part of the initial word line 151 is used as the word line 150. The initial word line 151 is etched to form the word lines 150 arranged at intervals in the first direction X. Forming the word lines 150 arranged at intervals may prevent adjacent word lines 150 from transmitting signals to each other.

Referring to FIG. 14, in some embodiments, after forming the word lines 150, the method further includes: forming an isolation structure 180 between adjacent word lines 150. The isolation structure 180 isolates the adjacent word lines 150, such that direct contact between the adjacent word lines 150 may be avoided, and thus the reliability of the semiconductor structure formed is improved.

According to the embodiments of the present disclosure, by forming the protective layer 140 surrounding the semiconductor channels 110 to form the source or drain, the source or drain may be prevented from being damaged in the process of subsequently etching the spacer 120, a part of the semiconductor channel 110 configured to form the source or drain may be prevented from being oxidized in the process of subsequently forming the gate dielectric layer 160, and the metal material may be prevented from being attached to part of the semiconductor channel 110 configured to form the source or drain when the word lines 150 are formed, and thus the reliability of the semiconductor structure may be improved.

Accordingly, another embodiment of the present disclosure also provides a method for fabricating a semiconductor structure. The method for fabricating a semiconductor structure provided in this embodiment of the present disclosure and the method for fabricating a semiconductor structure provided in the forgoing embodiment are substantially the same, and mainly differ in that: in this embodiment of the present disclosure, the protective layer is formed in one step, not formed in steps. The method for fabricating a semiconductor structure provided in another embodiment of the present disclosure will be described in detail below with reference to the accompanying drawings. It is to be noted that reference may be made to the previous embodiments for the detailed description of the same or corresponding parts, which is not described herein again.

Referring to FIG. 15, a substrate 200 is provided, where the substrate 200 includes semiconductor channels 210 arranged in an array along the first direction X and the second direction Y, and a part of the substrate 200 is exposed between adjacent semiconductor channels 210.

In some embodiments, initial semiconductor channels 211 are further included, where the initial semiconductor channels 211 are positioned on the bottom surfaces of the semiconductor channels 210.

In some embodiments, when forming the semiconductor channels 210, the method further includes: etching a part of the first initial spacers, such that a part of the first initial spacers are arranged at intervals along the first direction X, and the first initial spacers etched are used as the first spacers 222.

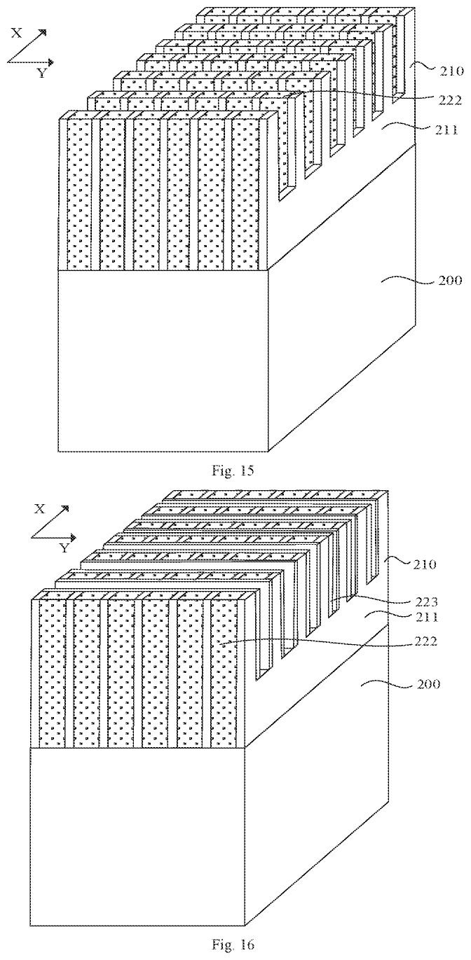

Referring to FIG. 16, initial side wall layers 223 are formed, where the initial side wall layers 223 cover the side walls of the semiconductor channels 210 arranged at intervals along the first direction X, and the initial side wall layers 223 also cover the side walls of the first spacers 222 arranged at intervals along the first direction X. Forming the initial side wall layers 223 may prevent the metal ions from diffusing into the semiconductor channels 210 when subsequently forming the bit lines, such that pollution of the semiconductor channels 210 may be avoided, and thus the reliability of the semiconductor structure formed may be improved.

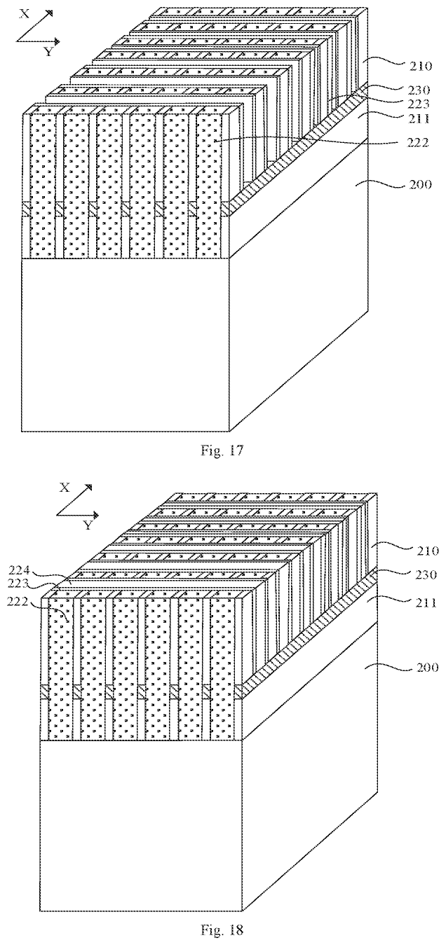

Referring to FIG. 17, a bit line 230 is formed, where the bit line 230 is positioned in the substrate 200, and a top surface of the bit line 230 contacts and connects the bottom surface of the semiconductor channel 210. In some embodiments, the bit line 230 may be formed by means of a metal semiconductor silicide process. A contact resistance between the bit line 230 formed by means of the metal semiconductor silicide process and the substrate 200 is lower, such that the performance of the semiconductor structure formed may be improved.

Referring to FIG. 18, a second initial spacer 224 is formed, where the second initial spacer 224 is positioned between adjacent initial side wall layers 223. Forming the second initial spacer 224 may provide a process basis for subsequent isolation of the bit lines 230 from the word lines.

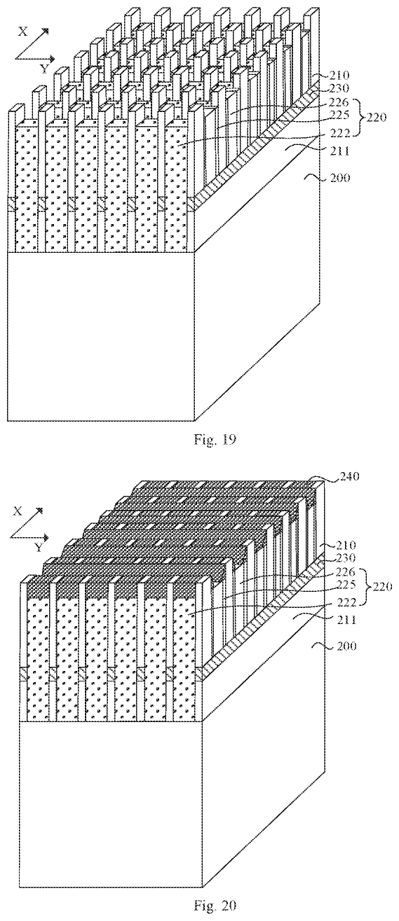

Referring to FIG. 19, the initial side wall layers 223 (referring to FIG. 18) and the second initial spacer 224 (referring to FIG. 18) are etched back, such that the top surfaces of the initial side wall layers 223 (referring to FIG. 18) and the top surface of the second initial spacer 224 (referring to FIG. 18) are lower than the top surfaces of the semiconductor channels 210. A remaining part of the initial side wall layers 223 (referring to FIG. 18) and a remaining part of the second initial spacer 224 (referring to FIG. 18) are used as the side wall layers 225 and the second spacers 226. The first spacer 222, the spacer layer 225 and the second spacer 226 are used as the spacer 220. The initial side wall layer 223 and the second initial spacer 224 are etched back to form the spacer 220, where the spacer 220 is positioned between adjacent semiconductor channels 210, and the top surface of the spacer 220 is lower than the top surface of the semiconductor channel 210.

Referring to FIG. 20, protective layers 240 are formed, where a part of the protective layers 240 are positioned on the top surfaces of the spacers 220 between the semiconductor channels 210 arranged along the second direction Y, and a part of the protective layers 240 are positioned on the top surfaces of the spacers 220 between the semiconductor channels 210 arranged along the first direction X, and the protective layers 240 are spaced along the first direction X. By forming the protective layers 240, a part of the semiconductor channel 110 configured to form the source or drain may be protected, and thus the reliability of the semiconductor structure formed may be improved.

In some embodiments, the step of forming the protective layers 240 includes: forming initial protective layers after the second spacers 226 are formed, where the initial protective layers cover the entire top surfaces of the spacers 220, and the initial protective layers also cover part of the side walls of the semiconductor channels 210 arranged at intervals along the first direction X; and etching the initial protective layers to form the protective layers 240 arranged at intervals along the first direction X. The initial protective layers are etched to form the protective layers 240 arranged at intervals, to provide a process basis for subsequently etching the spacers 220.

In some embodiments, the protective layer 240 and the spacer 220 are made of different materials. The material of the protective layer 240 is controlled to be different from that of the spacer 220, such that the protective layer 240 may be prevented from being etched in the process of subsequently etching the spacer 220, thereby avoiding reducing a protection effect of the protective layer 240.

In some embodiments, a thickness of the protective layer 240 formed is controlled within 20-70 nm in a direction perpendicular to the surface of the substrate 200. It is to be understood that the thickness of the protective layer 240 may be set according to a thickness of the region of each semiconductor channel 210 protected for forming the source or drain. When the thickness of the protective layer 240 is less than 20 nm, a part of the semiconductor channel 210 for forming the source or drain may be not protected, causing poor protection effect. When the thickness of the protective layer 240 is greater than 70 nm, a part of a region of the semiconductor channel 210 for forming a gate may likely be covered. In some other embodiments, the thickness of the protective layer 240 may also be other sizes, and may be adjusted according to actual situations.

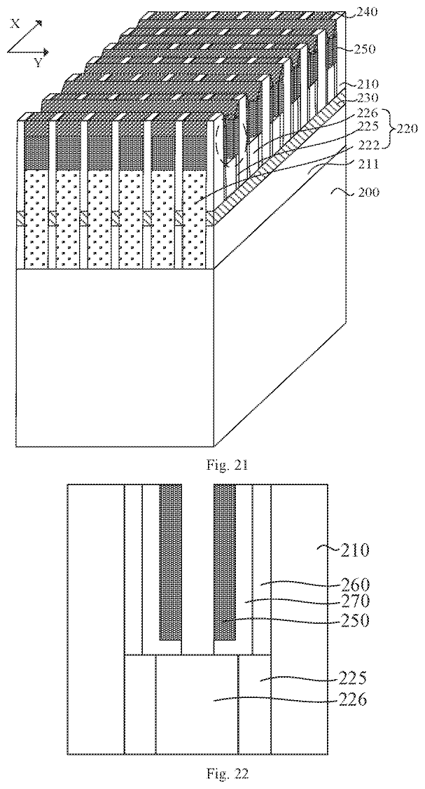

Referring to FIG. 21 and FIG. 22, FIG. 22 is a partial schematic enlarged drawing along a dotted line in FIG. 21. A word line 250 is formed, where the word line 250 is positioned between the protective layer 240 and the spacer 220.

In some embodiments, before forming the word line 250, the method further includes: forming a gate dielectric layer 260, where the gate dielectric layer 260 covers the side wall of the semiconductor channel 210. Forming the gate dielectric layer 260 may prevent direct contact between the word line 250 formed subsequently and the semiconductor channels 110, thereby preventing an exception from occurring in the semiconductor structure.

In some embodiments, after forming the gate dielectric layer 260, the method further includes: forming a diffusion barrier layer 270, where the diffusion barrier layer 270 is positioned on the top surface of the spacer 120. Forming the diffusion barrier layer 270 may prevent metal ions of subsequent word lines from diffusing into the semiconductor channels, thereby avoiding pollution of the semiconductor channels. Furthermore, forming the diffusion barrier layer 270 may improve the reliability of the semiconductor structure.

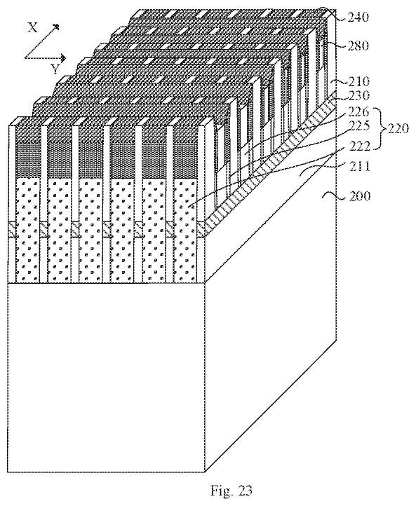

Referring to FIG. 23, in some embodiments, after forming the word lines 250, the method further includes: forming an isolation structure 280 between adjacent word lines 250. The isolation structure 280 isolates the adjacent word lines 250, such that direct contact between the adjacent word lines 250 may be avoided, and thus the reliability of the semiconductor structure formed is improved.

According to the embodiments of the present disclosure, by forming the protective layer 240 after the second spacers 226 are formed, the protective layer 240 can protect the source or drain from being damaged in the process of subsequently etching the spacer 220, a part of the semiconductor channel 210 configured to form the source or drain may be prevented from being oxidized in the process of subsequently forming the gate dielectric layer 260, and the metal material may be prevented from being attached to part of the semiconductor channel 210 configured to form the source or drain when the word lines 250 are formed. In this way, the reliability of the semiconductor structure may be improved.

Yet another embodiment of the present disclosure also provides a semiconductor structure, which may be formed by some or all of the steps of the above method for fabricating a semiconductor structure.

Those of ordinary skill in the art can understand that the above-mentioned embodiments are some embodiments for realizing the present disclosure, but in practical applications, various changes may be made to them in form and details without departing from the spirit and scope of the embodiments of the present disclosure. Any person skilled in the art can make their own changes and modifications without departing from the spirit and scope of the embodiments of the present disclosure. Therefore, the protection scope of the embodiments of the present disclosure shall be subject to the scope defined by the claims.

What is claimed is:

1. A method for fabricating a semiconductor structure, comprising:
providing a substrate, the substrate comprising semiconductor channels arranged in an array along a first direction and a second direction, and a part of the substrate being exposed between adjacent two of the semiconductor channels;
forming a spacer, the spacer being positioned between adjacent two of the semiconductor channels, and a top surface of the spacer being lower than top surfaces of the semiconductor channels;
forming a bit line positioned in the substrate, a top surface of the bit line contacting and connecting bottom surfaces of the semiconductor channels;
forming a protective layer, a part of the protective layer being positioned on the top surface of the spacer between adjacent two of the semiconductor channels arranged along the second direction, and another part of the protective layer being positioned on the top surface of the spacer between adjacent two of the semiconductor channels arranged along the first direction; and
forming a word line, the word line being positioned between the protective layer and the spacer.

2. The method for fabricating a semiconductor structure according to claim 1, wherein the forming the spacer comprises: forming first spacers, part of the first spacers being arranged at intervals along the first direction, and the first spacers being positioned between the semiconductor channels arranged along the second direction;
forming side wall layers, the side wall layers covering side walls of the semiconductor channels arranged at intervals along the first direction, and the side wall layers also covering side walls of the first spacers arranged at intervals along the first direction; and
forming second spacers, each of the second spacers being positioned between adjacent two of the side wall layers, and the first spacers, the side wall layers, and the second spacers constituting the spacer.

3. The method for fabricating a semiconductor structure according to claim 2, wherein the forming the protective layer comprises: forming a first protective layer, the first protective layer being positioned on top surfaces of the first spacers; and
forming second protective layers, the second protective layers being positioned on side walls of the first protective layers arranged at intervals along the first direction, the second protective layers further covering the side walls of the semiconductor channels arranged at intervals along the first direction, and the first protective layers and the second protective layers constituting the protective layer.

4. The method for fabricating a semiconductor structure according to claim 3, wherein the forming the first protective layers comprises: forming first initial protective layers before the side wall layers are formed, the first initial protective layers being positioned on top surfaces of the first spacers and extending along the first direction; and
etching the first initial protective layers to form the first protective layers arranged at intervals along the first direction.

5. The method for fabricating a semiconductor structure according to claim 4, wherein the forming the second protective layers comprises: forming second initial protective layers after the second spacers are formed, the second initial protective layers covering the side walls of the first protective layers, top surfaces of the side wall layers, and entire top surfaces of the second spacers; and
etching the second initial protective layers to form the second protective layers arranged at intervals along the first direction.

6. The method for fabricating a semiconductor structure according to claim 2, wherein the forming the protective layer comprises: forming an initial protective layer after the second spacers are formed, the initial protective layer covering the entire top surface of the spacer, and the initial protective layer further covering part of the side walls of the semiconductor channels arranged at intervals along the first direction; and
etching the initial protective layer to form the protective layer arranged at intervals along the first direction.

7. The method for fabricating a semiconductor structure according to claim 3, wherein a material of the protective layer is different from a material of the spacer.

8. The method for fabricating a semiconductor structure according to claim 3, wherein a thickness of the protective layer formed is controlled within 20-70 nm in a direction perpendicular to a surface of the substrate.

9. The method for fabricating a semiconductor structure according to claim 1, wherein the forming the bit line comprises:
forming a bit line metal layer, the bit line metal layer being positioned between adjacent two of the semiconductor channels arranged at intervals along the first direction;
converting a part of the substrate into an initial bit line by means of a first annealing process;
removing the bit line metal layer; and
converting the initial bit line into the bit line by means of a second annealing process.

10. The method for fabricating a semiconductor structure according to claim 9, wherein a process temperature of the first annealing process is lower than a process temperature of the second annealing process.

11. The method for fabricating a semiconductor structure according to claim 9, wherein the process temperature of the first annealing process is 400° C. to 700° C., and the process temperature of the second annealing process is 750° C. to 1,000° C.

12. The method for fabricating a semiconductor structure according to claim 1, wherein the forming the word line comprises: etching the spacer to expose the side walls of the semiconductor channels;
forming an initial word line, the initial word line being positioned on the top surface of the spacer; and
etching the initial word line using the protective layer as a mask until the spacer is exposed, a remaining part of the initial word line being used as the word line.

13. The method for fabricating a semiconductor structure according to claim 12, wherein before forming the initial word line, the method further comprises: forming a gate dielectric layer, the gate dielectric layer covering the side walls of the semiconductor channels.

14. The method for fabricating a semiconductor structure according to claim 13, wherein after forming the gate dielectric layer, the method further comprises: forming a diffusion barrier layer, the diffusion barrier layer being positioned on the top surface of the spacer.

15. A semiconductor structure, formed by the method for fabricating the semiconductor structure according to claim 1.
